(19) United States
(12) Patent Application Publication
(10) Pub. No.: US 2006/0097793 A1
(43) Pub. Date: May 11, 2006

(54) CONTROL DEVICE OF A PLL AND CONTROL METHOD THEREOF

(76) Inventor: Ming-Cheng Chiang, Hsin-Chu (TW)

Correspondence Address: NORTH AMERICA INTELLECTUAL PROPERTY CORPORATION, P.O. BOX 506, MERRIFIELD, VA, 22116, US

(21) Appl. No.: 11/163,465

(22) Filed: Oct. 20, 2005

(30) Foreign Application Priority Data
Oct. 26, 2004 (TW) 093132379

(51) Int. Cl. H03L 7/00

(52) U.S. Cl. 331/16

(57) ABSTRACT

A control device of a phase-locked loop (PLL) for controlling an oscillator of the PLL to generate a clock signal, includes: a phase frequency detector (PFD) for generating at least one digital signal according to the phase and the frequency of at least one input signal; a digital filtering module coupled to the PFD for generating a first filtered signal and a second filtered signal according to the digital signal; and at least one digital-to-analog converter (DAC) for performing digital-to-analog conversion on the first and second filtered signals to output a first analog signal and a second analog signal to the oscillator. The oscillator generates the clock signal according to the first and second analog signals.

### BACKGROUND OF THE INVENTION

1. Field of the Invention

The present invention relates to a phase-locked loop (PLL), and more particularly, to a control device of a PLL and a control method thereof.

2. Description of the Prior Art

Phase-locked loops (PLLs) include analog PLLs, digital PLLs, and hybrid PLLs, where hybrid PLLs have both digital components and analog components. Typically, a hybrid PLL comprises an oscillator, which is controlled by utilizing an analog signal. Some other components in the hybrid PLL generate a digital signal according to a clock signal generated by the oscillator, where the digital signal is converted into the analog signal utilizing a digital-to-analog converter (DAC). The frequency of the clock signal typically corresponds to the magnitude of the analog signal.

In general, the greater number of bits a DAC may process, the slower the operation speed of the DAC. Conversely, the faster the operation speed of a DAC, the fewer number of bits the DAC may process. According to the prior art, in order to balance the number of bits that a DAC may process and the operation speed of the DAC in a hybrid PLL, one of the two characteristics (i.e. the number of bits that the DAC may process and the operation speed of the DAC) is typically degraded. Therefore, the possibility of enhancing performance of the prior art hybrid PLL is limited. It is suggested that a hybrid PLL comprising an oscillator having two control terminals can be utilized to resolve this problem. However, the oscillator having two control terminals is not readily available, and may increase the manufacturing or material cost due to the specialized design of the oscillator.

### SUMMARY OF THE INVENTION

It is therefore an objective of the claimed invention to provide a control device of a phase-locked loop (PLL) and a control method thereof to solve the above-mentioned problem.

According to one embodiment of the claimed invention, a control device of a PLL for controlling an oscillator of the PLL to generate a clock signal is disclosed. The control device comprises: a phase frequency detector (PFD) for generating at least one digital signal according to the phase and the frequency of at least one input signal; a digital filtering module coupled to the PFD for generating a first filtered signal and a second filtered signal according to the digital signal; and at least one digital-to-analog converter (DAC) for performing digital-to-analog conversion on the first and second filtered signals to output a first analog signal and a second analog signal to the oscillator. The oscillator generates the clock signal according to the first and second analog signals.

According to one embodiment of the claimed invention, a control method of a PLL for controlling an oscillator of the PLL to generate a clock signal is further disclosed. The control method comprises: generating at least one digital signal according to the phase and the frequency of at least one input signal; generating a first filtered signal and a second filtered signal according to the digital signal; performing digital-to-analog conversion on the first filtered signal to generate a first analog signal; performing digital-to-analog conversion on the second filtered signal to generate a second analog signal; and controlling the oscillator according to the first and second analog signals to generate the clock signal.

These and other objectives of the claimed invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a phase-locked loop (PLL) according to a first embodiment of the present invention.

FIG. 2 is a diagram of a PLL according to a second embodiment of the present invention.

FIG. 3 is a diagram of a PLL according to a third embodiment of the present invention.

### DETAILED DESCRIPTION

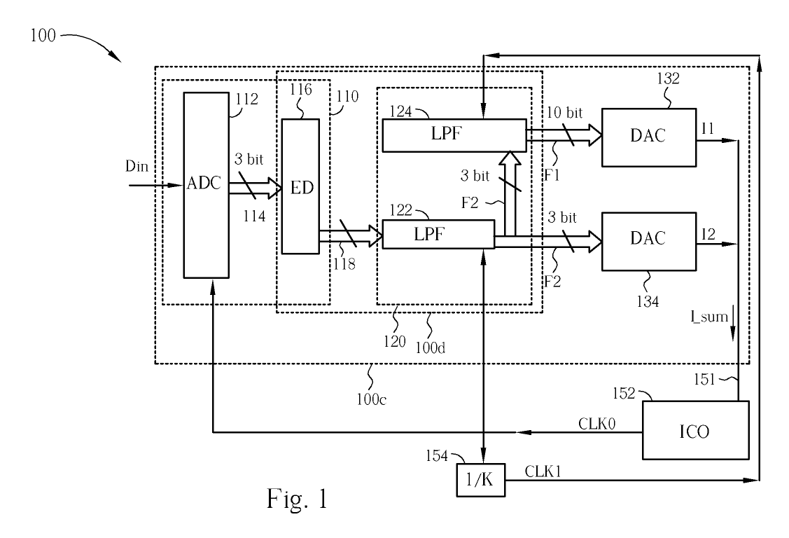

Please refer to FIG. 1. FIG. 1 is a diagram of a phase-locked loop (PLL) 100 according to a first embodiment of the present invention. According to this embodiment, the present invention provides a control device 100c of the PLL 100 and a control method thereof, for controlling an oscillator 152 of the PLL 100. The oscillator 152 shown in FIG. 1 is a current-controlled oscillator (CCO), i.e. an ICO, where operation principles thereof are well known in the art and therefore not explained in detail here. As shown in FIG. 1, the control device 100c comprises a phase frequency detector (PFD) 110, a digital filtering module 120, and two DACs 132 and 134. In addition, the PLL 100 further comprises a frequency divider 154, which is utilized for performing a frequency dividing operation on a clock signal CLK0 generated by the oscillator 152 to generate a clock signal CLK1. Operation principles of the frequency divider 154 are well known in the art and therefore not explained in detail here.

The PFD 110 generates at least one digital signal 118 according to the phase and frequency of an input signal Din. In this embodiment, the PFD 110 comprises an analog-to-digital converter (ADC) 112 and an edge detector (ED) 116, so the digital signal 118 is also referred to as the edge detection signal. The ADC 112 utilizes the clock signal CLK0 as a sampling clock, and samples the input signal Din according to the clock signal CLK0 to generate a sampled signal 114. The ED 116 detects waveforms of the sampled signal 114 to generate the digital signal 118. Please note the architecture of the PFD 110 mentioned above is an implementation choice and not a limitation of the present invention.

In addition, the digital filtering module 120 is for filtering the digital signal 118 to generate two filtered signals F1 and F2. The filtered signal F2 controls the oscillator 152 to adjust the frequency of the clock signal CLK0 in a faster response speed. It is noted that the filtered signals F1 and F2 respectively correspond to an M-bit digital value having M bits and an N-bit digital value having N bits, where M is greater than N. Therefore, the filtered signal F1 has a larger dynamic range than that of the filtered signal F2. In this embodiment, the digital filtering module 120 comprises two low pass filters (LPFs) 122 and 124. The LPF 122 performs low pass filtering on the digital signal 118 to generate the filtered signal F2, where the filtered signal F2 has a 3-bit digital value. The LPF 124 performs low pass filtering on the filtered signal F2 to generate the filtered signal F1, where the filtered signal F1 has a 10-bit digital value. Please note the architecture of the digital filtering module 120 mentioned above is an implementation choice and not a limitation of the present invention. In addition, in this embodiment, a digital signal processor 100d is utilized for implementing the operations of the ED 116 and the digital filtering module 120. Besides, the LPF 124 can be realized by using a digital integrator whose function is well known in this art.

According to the present invention, the DACs mentioned above are utilized for performing digital-to-analog conversion on the filtered signals F1 and F2 generated by the digital filtering module 120 to output a first analog signal and a second analog signal to the oscillator 152. Furthermore, the oscillator 152 is for controlling the frequency of the clock signal CLK0 according to the sum of the first and second analog signals. In this embodiment, the first and second analog signals are current signals 11 and 12 shown in FIG. 1. As shown in FIG. 1, the DAC 132 performs digital-to-analog conversion on the filtered signal F1 to generate the current signal 11. Similarly, the DAC 134 performs digital-to-analog conversion on the filtered signal F2 to generate the current signal 12. According to this embodiment, the output terminals of the DACs 132 and 134 are coupled to an input terminal 151 of the oscillator 152. Therefore, the control device 100c of the present invention controls the frequency of the clock signal CLK0 generated by the oscillator 152 according to the total current I_sum of the current signals I1 and I2. Please note that the number of bits of a DAC does not limit the magnitude of the current generated by the DAC. In addition, the DACs 132 and 134 are respectively an M-bit DAC and an N-bit DAC where M is greater than N, such that the DAC 134 controls the oscillator 152 to adjust the frequency of the clock signal CLK0 in a faster response speed.

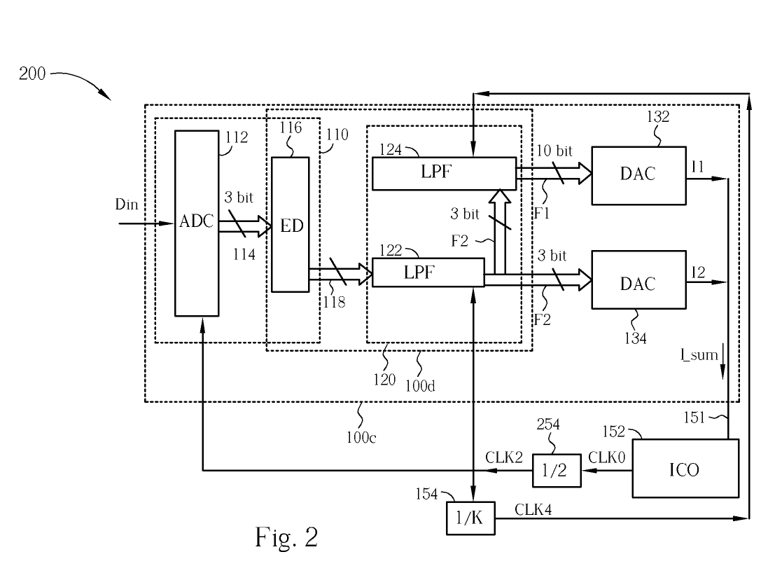

Please refer to FIG. 2. FIG. 2 is a diagram of a PLL according to a second embodiment of the present invention. The second embodiment is similar to the first embodiment, where the differences between them are described as follows. The PLL 200 further comprises a frequency divider 254 for performing a frequency dividing operation on the clock signal CLK0 generated by the oscillator 152 to generate a clock signal CLK2. As shown in FIG. 2, the frequency divider 154 and the control device 100c of this embodiment operate according to the clock signals CLK2 and CLK4. Other descriptions similar to those of the first embodiment are not repeated here.

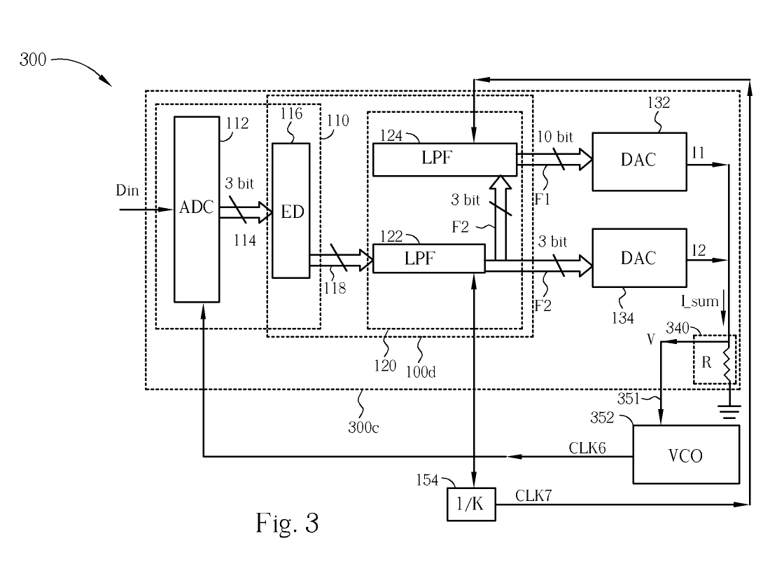

Please refer to FIG. 3. FIG. 3 is a diagram of a PLL 300 according to a third embodiment of the present invention. The third embodiment is similar to the first embodiment, where the differences between them are described as follows. The oscillator 352 of this embodiment is a voltage-controlled oscillator (VCO), where operation principles thereof are well known in the art and therefore not explained in detail here. In addition to the PFD 110, the digital filtering module 120, and the DACs 132 and 134 mentioned above, the control device 300c of this embodiment further comprises a current-to-voltage converter 340 coupled to the output terminals of the DACs 132 and 134 and an input terminal of the oscillator 352, where the current-to-voltage converter 340 is utilized for converting the total current I_sum mentioned above into a voltage signal V. The control device 300c controls the VCO 352 according to the voltage signal V. In this embodiment, the current-to-voltage converter 340 comprises at least one resistor whose resistance value is R, so the magnitude (I_sum*R) of the voltage signal V corresponds to the magnitude of the total current I_sum. Other descriptions similar to those of the first embodiment are not repeated here.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A control device of a phase-locked loop (PLL) for controlling an oscillator of the PLL to generate a clock signal, the control device comprising:
a phase frequency detector (PFD) for generating a digital signal according to an input signal;
a digital filtering module coupled to the PFD for generating a first filtered signal having M bits and a second filtered signal having N bits according to the digital signal;
a first digital-to-analog converting unit for converting the first filtered signal into a first analog signal; and
a second digital-to-analog converting unit for converting the second filtered signal into a second analog signal;
wherein the oscillator generates the clock signal according to the first analog signal and the second analog signal.

2. The control device of claim 1, wherein the oscillator generates the clock signal according to the sum of the first and second analog signals.

3. The control device of claim 1, wherein the first and second analog signals are current signals.

4. The control device of claim 3, further comprising a current-to-voltage converter for converting the current signals into voltage signals.

5. The control device of claim 1, wherein the oscillator is a current-controlled oscillator or a voltage-controlled oscillator.

6. The control device of claim 1, wherein the M and the N are unequal.

7. The control device of claim 1, wherein the digital filtering module filters the second filtered signal to generate the first filtered signal.

8. The control device of claim 7, wherein the digital filtering module comprises a digital integrator for integrating the second filtered signal to generate the first filtered signal.

9. The control device of claim 1, wherein the PFD further comprises:
an analog-to-digital converter (ADC) for sampling the input signal to generate a sampled signal; and
an edge detector coupled to the ADC for detecting waveforms of the sampled signal to generate the digital signal.

10. A control method of a phase-locked loop (PLL) for controlling an oscillator of the PLL to generate a clock signal, the control method comprising:
generating at least one digital signal according to an input signal;
generating a first filtered signal having M bits and a second filtered signal having N bits according to the digital signal;
performing digital-to-analog conversion on the first filtered signal to generate a first analog signal;
performing digital-to-analog conversion on the second filtered signal to generate a second analog signal; and
controlling the oscillator to generate the clock signal in response to the first and the second analog signals.

11. The control method of claim 10, wherein the oscillator is controlled to generate the clock signal according to the sum of the first and second analog signals.

12. The control method of claim 10, wherein the first and second analog signals are current signals.

13. The control method of claim 12, further comprising a step of converting the current signals into voltage signals.

14. The control method of claim 10, wherein the oscillator is a current-controlled oscillator or a voltage-controlled oscillator.

15. The control method of claim 10, wherein the M and the N are unequal.

16. The control method of claim 10, wherein the step of generating the first and second filtered signals further comprises:
generating the second filtered signal according to the digital signal; and
filtering the second filtered signal to generate the first filtered signal.

17. The control method of claim 16, wherein the step of filtering the second filtered signal is digitally integrating the second filtered signal to generate the first filtered signal.

18. The control method of claim 10, wherein the step of generating the digital signal further comprises:
sampling the input signal to generate a sampled signal; and
detecting waveforms of the sampled signal to generate the digital signal.
